(19) United States
(12) Patent Application Publication
(10) Pub. No.: US 2026/0271783 A1
(43) Pub. Date: Sep. 10, 2026

(54) SEMICONDUCTOR DEVICES, SYSTEMS, AND METHODS FOR FORMING THE SAME

(71) Applicant: Yangtze Memory Technologies Co., Ltd., Wuhan (CN)

(72) Inventors: Danyang Wei, Wuhan (CN); Zongliang Huo, Wuhan (CN); Liang Chen, Wuhan (CN); Shiqi Huang, Wuhan (CN); Wei Liu, Wuhan (CN); Wen Li, Wuhan (CN); Lin Miao, Wuhan (CN); Jiahao Chen, Wuhan (CN)

(21) Appl. No.: 19/177,129

(22) Filed: Apr. 11, 2025

Related U.S. Application Data
(63) Continuation of application No. PCT/CN2025/081285, filed on Mar. 7, 2025.

(51) Int. Cl. H01L 23/00; H01L 23/528; H01L 25/16; H10B 80/00

(52) U.S. Cl. CPC H10W 90/00; H10B 80/00; H10W 20/43; H10W 72/019; H10W 80/312; H10W 80/327; H10W 90/792

(57) ABSTRACT

A semiconductor device includes a peripheral circuit structure. The peripheral circuit structure includes a periphery circuit disposed on a substrate and a first interconnection structure disposed on the periphery circuit. The first interconnection structure includes a first conductive structure extending in a first direction, a second conductive structure extending in the first direction, a third conductive structure extending in the first direction, wherein the second conductive structure is disposed between the first conductive structure and the third conductive structure in a second direction perpendicular to the first direction, and a contact structure extending in the second direction in direct contact with the first conductive structure and the third conductive structure.

### CROSS-REFERENCE TO RELATED APPLICATIONS

This application is a continuation of International Application No. PCT/CN2025/081285, filed on Mar. 7, 2025, which is hereby incorporated by reference in its entirety.

### BACKGROUND

The present disclosure relates to semiconductor devices, systems, and methods for forming semiconductor devices, specifically to memory devices and fabrication methods of the memory.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

According to one aspect of the present disclosure, a semiconductor device is disclosed. The semiconductor device includes a peripheral circuit structure. The peripheral circuit structure includes a periphery circuit disposed on a substrate and a first interconnection structure disposed on the periphery circuit. The first interconnection structure includes a first conductive structure extending in a first direction, a second conductive structure extending in the first direction, a third conductive structure extending in the first direction, wherein the second conductive structure is disposed between the first conductive structure and the third conductive structure in a second direction perpendicular to the first direction, and a contact structure extending in the second direction in direct contact with the first conductive structure and the third conductive structure.

In some implementations, the semiconductor device further includes a memory array structure stacked with the peripheral circuit structure along the second direction.

In some implementations, the periphery circuit includes a first periphery circuit and a second periphery circuit, and the first periphery circuit is connected to the third conductive structure through the contact structure and the first conductive structure.

In some implementations, the second periphery circuit is connected to the second conductive structure.

In some implementations, the first periphery circuit includes a sense amplifier or a word line driver.

In some implementations, a first contacting surface between the contact structure and the third conductive structure is greater than a second contacting surface between the contact structure and the first conductive structure.

In some implementations, the periphery circuit overlaps the memory array structure in the second direction.

In some implementations, projections of two first periphery circuits controlling two adjacent memory blocks are in a same memory block of the memory array structure in the second direction.

In some implementations, an extension direction of the sense amplifier is perpendicular to an extension direction of the word line driver.

In some implementations, the peripheral circuit structure is stacked with the memory array structure through a bonding layer, and the bonding layer comprises a dielectric structure and a conductive bonding contact structure.

In some implementations, the third conductive structure is in direct contact with the conductive bonding contact structure.

In some implementations, the third conductive structure is in contact with the conductive bonding contact structure.

In some implementations, the third conductive structure includes the conductive bonding contact structure.

In some implementations, the first periphery circuit is coupled to a word line of the memory array structure or a bit line of the memory array structure.

According to one aspect of the present disclosure, a system is disclosed. The system includes a semiconductor device and a memory controller coupled to the semiconductor device. The semiconductor device includes a peripheral circuit structure. The peripheral circuit structure includes a periphery circuit disposed on a substrate and a first interconnection structure disposed on the periphery circuit. The first interconnection structure includes a first conductive structure extending in a first direction, a second conductive structure extending in the first direction, a third conductive structure extending in the first direction, wherein the second conductive structure is disposed between the first conductive structure and the third conductive structure in a second direction perpendicular to the first direction, and a contact structure extending in the second direction in direct contact with the first conductive structure and the third conductive structure.

According to one aspect of the present disclosure, a method for forming a semiconductor device is disclosed. A peripheral circuit structure is formed on a substrate. The peripheral circuit structure includes a periphery circuit on the substrate, a first conductive structure on the periphery circuit extending in a first direction, and a second conductive structure on the first conductive structure extending in the first direction. A contact structure is formed extending in a second direction perpendicular to the first direction in direct contact with the first conductive structure. A third conductive structure is formed on the contact structure extending in the first direction. The third conductive structure is in direct contact with the contact structure.

In some implementations, the periphery circuit includes a first periphery circuit and a second periphery circuit, and the first periphery circuit is connected to the third conductive structure through the contact structure and the first conductive structure.

In some implementations, the first conductive structure is formed on the first periphery circuit and the second periphery circuit. The first conductive structure is coupled to the first periphery circuit. The second conductive structure is formed on the first conductive structure. The second conductive structure is coupled to the second periphery circuit.

In some implementations, the first periphery circuit includes a sense amplifier or a word line driver.

In some implementations, an opening is formed extending in the second direction exposing the first conductive structure. The contact structure is formed in the opening.

In some implementations, the contact structure is insulated with the second conductive structure.

In some implementations, the contact structure is formed in the opening without contacting the second conductive structure.

In some implementations, a memory array structure is formed, and the memory array structure is bonded with the peripheral circuit structure.

In some implementations, a memory array structure is formed on the peripheral circuit structure.

### BRIEF DESCRIPTION OF THE DRAWINGS

The accompanying drawings, which are incorporated herein and form a part of the specification, illustrate implementations of the present disclosure and, together with the description, further serve to explain the present disclosure and to enable a person skilled in the pertinent art to make and use the present disclosure.

FIG. 1A illustrates a schematic view of a cross-section of a 3D memory device, according to some aspects of the present disclosure.

FIG. 1B illustrates a schematic view of a cross-section of another 3D memory device, according to some aspects of the present disclosure.

FIG. 2 illustrates a schematic diagram of a memory device including peripheral circuits and an array of memory cells each having a vertical transistor, according to some aspects of the present disclosure.

FIG. 3 illustrates a schematic circuit diagram of a memory device including peripheral circuits and an array of dynamic random-access memory (DRAM) cells, according to some aspects of the present disclosure.

FIG. 4 illustrates a schematic circuit diagram of a memory device including peripheral circuits and an array of phase-change memory (PCM) cells, according to some aspects of the present disclosure.

FIG. 5 illustrates a side view of a cross-section of a 3D memory device including a peripheral circuit structure and a memory array structure stacked with the peripheral circuit structure.

FIG. 6 illustrates a schematic plan view of a memory array structure, according to some aspects of the present disclosure.

FIG. 7 illustrates a schematic plan view of a peripheral circuit structure, according to some aspects of the present disclosure.

FIG. 8 illustrates a schematic plan view of a peripheral circuit structure, according to some aspects of the present disclosure.

FIGS. 9-14 illustrate cross-sectional views of an exemplary semiconductor device at various stages of a fabrication process, according to some implementations of the present disclosure.

FIG. 15 illustrates a flowchart of a method for forming an exemplary semiconductor device, according to some implementations of the present disclosure.

FIGS. 16-19 illustrate cross-sectional views of another exemplary semiconductor device at various stages of a fabrication process, according to some implementations of the present disclosure.

FIG. 20 illustrates a block diagram of an exemplary system having a memory device, according to some implementations of the present disclosure.

FIG. 21A illustrates a diagram of an exemplary memory card having a memory device, according to some implementations of the present disclosure.

FIG. 21B illustrates a diagram of an exemplary solid-state drive (SSD) having a memory device, according to some implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

When vertically stacking a memory array wafer with a peripheral CMOS wafer, interconnect routing is crucial because it impacts both the required area and electrical performance. Typically, the array wafer and peripheral wafer are separately manufactured, and then bonded via hybrid bonding and pad-out. The sense amplifiers must be connected to the bit lines and the word line driver to the word lines via interconnects. As a result, much of the space beneath the array wafer is used for routing these components. Some of the peripheral device area could be used, with the CMOS pad-out structure provided, but the cost of this structure remains high.

To address one or more of the aforementioned issues, the present disclosure introduces a solution in which a contact structure can extend from the lower metal layer to the top metal layer without going through the other middle metal layers. By implementing the contact structure described in this application, which extends through multiple metal layers to replace the via-metal-via structure, the sense amplifiers and/or word line drivers can be directly connected to the top metal layer. As a result, the contact structure reduces routing path and space requirements, frees up additional space for other components, such as power lines, and reduces peripheral area. Additionally, the contact structure offers lower resistance than the via-metal-via structure, which can help minimize voltage drop loss in power lines.

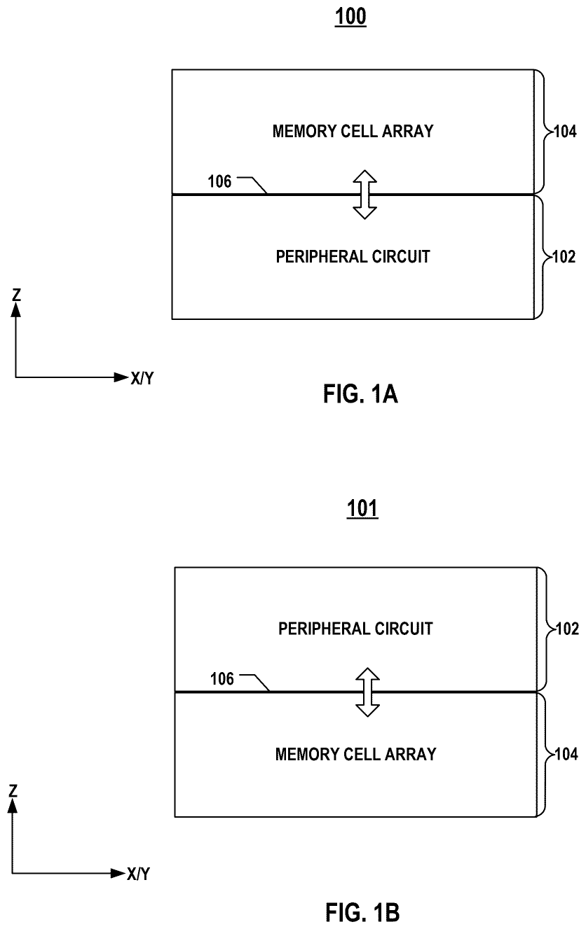

FIG. 1A illustrates a schematic view of a cross-section of a 3D memory device 100 according to some aspects of the present disclosure. 3D memory device 100 represents an example of a bonded chip. The components of 3D memory device 100 (e.g., memory cell array and peripheral circuits) can be formed separately on different substrates and then joined to form a bonded chip. 3D memory device 100 can include a first semiconductor structure 102 (also referred to herein as “peripheral circuit structure”) including the peripheral circuits of a memory cell array. 3D memory device 100 can also include a second semiconductor structure 104 (also referred to herein as “memory array structure”) including the memory cell array. The peripheral circuits (a.k.a. control and sensing circuits) can include any suitable digital, analog, and/or mixed-signal circuits used for facilitating the operations of the memory cell array. For example, the peripheral circuit can include one or more of a page buffer, a decoder (e.g., a row decoder and a column decoder), a sense amplifier, a driver (e.g., a word line driver, a precharge voltage driver, and a discharge voltage driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in first semiconductor structure 102 use complementary metal-oxide-semiconductor (CMOS) technology, e.g., which can be implemented with logic processes, according to some implementations.

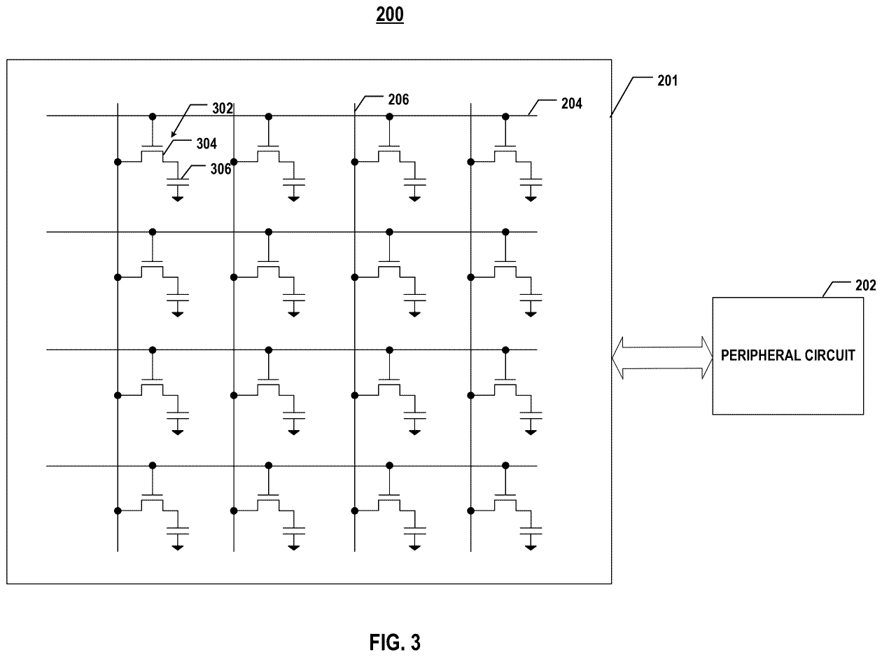

As shown in FIGS. 1A, 3D memory device 100 can also include second semiconductor structure 104 including an array of memory cells (memory cell array) that can use transistors as the switch and selecting devices. In some implementations, the memory cell array includes an array of DRAM cells. For ease of description, a DRAM cell array may be used as an example for describing the memory cell array in the present disclosure. But it is understood that the memory cell array is not limited to DRAM cell array and may include any other suitable types of memory cell arrays that can use transistors as the switch and selecting devices, such as phase-change memory (PCM) cell array, static random-access memory (SRAM) cell array, ferroelectric random-access memory (FRAM) cell array, resistive memory cell array, magnetic memory cell array, spin transfer torque (STT) memory cell array. to name a few, or any combination thereof.

Second semiconductor structure 104 can be a DRAM device in which memory cells are provided in the form of an array of DRAM cells. In some embodiments, each DRAM cell includes a capacitor for storing a bit of data as a positive or negative electrical charge as well as one or more transistors (a.k.a. pass transistors) that control (e.g., switch and selecting) access to it. In some implementations, each DRAM cell is a one-transistor, one-capacitor (1T1C) cell. Since transistors always leak a small amount of charge, the capacitors will slowly discharge, causing information stored in them to drain. As such, a DRAM cell has to be refreshed to retain data, for example, by the peripheral circuit in first semiconductor structure 102, according to some implementations.

As shown in FIGS. 1A, 3D memory device 100 further includes a bonding interface 106 vertically between (in the vertical direction, e.g., the Z-direction in FIG. 1A) first semiconductor structure 102 and second semiconductor structure 104. First and second semiconductor structures 102 and 104 can be fabricated separately (and in parallel in some implementations) such that the thermal budget of fabricating one of first and second semiconductor structures 102 and 104 does not limit the processes of fabricating another one of first and second semiconductor structures 102 and 104. Moreover, a large number of interconnects (e.g., bonding contacts) can be formed through bonding interface 106 to make direct, short-distance (e.g., micron-level) electrical connections between first semiconductor structure 102 and second semiconductor structure 104, as opposed to the long-distance (e.g., millimeter or centimeter-level) chip-to-chip data bus on the circuit board, such as printed circuit board (PCB), thereby eliminating chip interface delay and achieving high-speed input/output (I/O) throughput with reduced power consumption. Data transfer between the memory cell array in second semiconductor structure 104 and the peripheral circuits in first semiconductor structure 102 can be performed through the interconnects (e.g., bonding contacts) across bonding interface 106. By vertically integrating first and second semiconductor structures 102 and 104, the chip size can be reduced, and the memory cell density can be increased.

It is understood that the relative positions of stacked first and second semiconductor structures 102 and 104 are not limited. FIG. 1B illustrates a schematic view of a cross-section of another exemplary 3D memory device 101, according to some implementations. Different from 3D memory device 100 in FIG. 1A in which second semiconductor structure 104 including the memory cell array is above first semiconductor structure 102 including the peripheral circuits, in 3D memory device 101 in FIG. 1B, first semiconductor structure 102 including the peripheral circuit is above second semiconductor structure 104 including the memory cell array. Nevertheless, bonding interface 106 is formed vertically between first and second semiconductor structures 102 and 104 in 3D memory device 101, and first and second semiconductor structures 102 and 104 are jointed vertically through bonding (e.g., hybrid bonding) according to some implementations. Hybrid bonding, also known as “metal/dielectric hybrid bonding,” is a direct bonding technology (e.g., forming bonding between surfaces without using intermediate layers, such as solder or adhesives) and can obtain metal-metal (e.g., copper-to-copper) bonding and dielectric-dielectric (e.g., silicon oxide-to-silicon oxide) bonding simultaneously. Data transfer between the memory cell array in second semiconductor structure 104 and the peripheral circuits in first semiconductor structure 102 can be performed through the interconnects (e.g., bonding contacts) across bonding interface 106.

It is noted that X, Y, and Z axes are included in FIGS. 1A and 1B to further illustrate the spatial relationship of the components in 3D memory devices 100 and 101. The substrate of the 3D memory device includes two lateral surfaces extending laterally in the X-Y plane: a top surface on the front side of the wafer on which the semiconductor devices can be formed, and a bottom surface on the backside opposite to the front side of the wafer. The Z-axis is perpendicular to both the X and Y axes. As used herein, whether one component (e.g., a layer or a device) is “on,” “above,” or “below” another component (e.g., a layer or a device) of the 3D memory device is determined relative to the substrate of the 3D memory device in the Z-direction (the vertical direction perpendicular to the X-Y plane, e.g., the thickness direction of the substrate) when the substrate is positioned in the lowest plane of the 3D memory device in the Z-direction. The same notion for describing the spatial relationships is applied throughout the present disclosure.

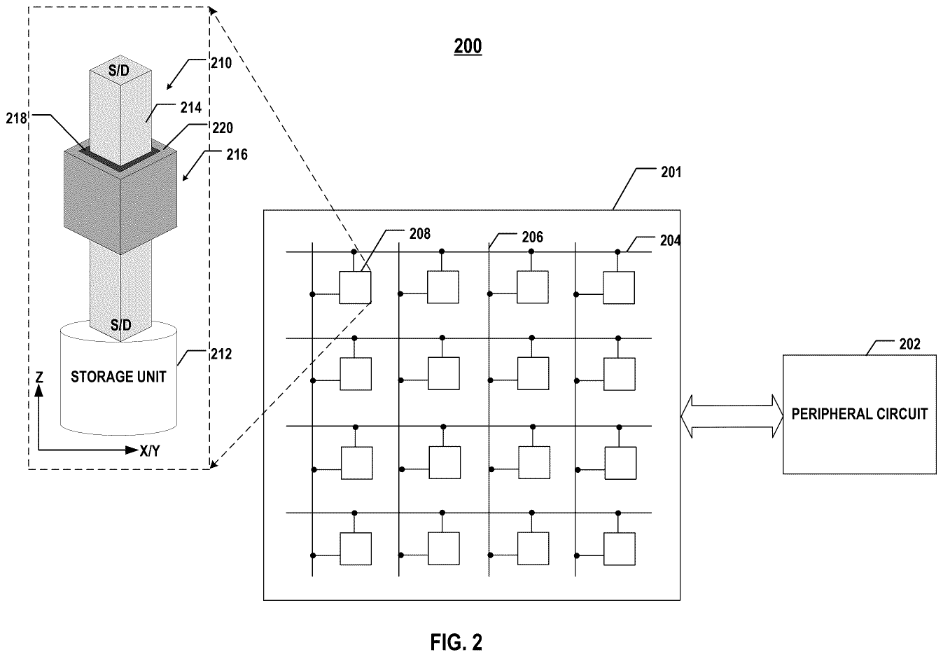

FIG. 2 illustrates a schematic diagram of a memory device 200 including peripheral circuits and an array of memory cells each having a vertical transistor, according to some aspects of the present disclosure. Memory device 200 can include a memory cell array 201 and peripheral circuits 202 coupled to memory cell array 201. 3D memory devices 100 and 101 may be examples of memory device 200 in which memory cell array 201 and peripheral circuits 202 may be included in second and first semiconductor structures 104 and 102, respectively. Memory cell array 201 can be any suitable memory cell array in which each memory cell 208 includes a vertical transistor 210 and a storage unit 212 coupled to vertical transistor 210. In some implementations, memory cell array 201 is a DRAM cell array, and storage unit 212 is a capacitor for storing charge as the binary information stored by the respective DRAM cell. In some implementations, memory cell array 201 is a PCM cell array, and storage unit 212 is a PCM element (e.g., including chalcogenide alloys) for storing binary information of the respective PCM cell based on the different resistivities of the PCM element in the amorphous phase and the crystalline phase. In some implementations, memory cell array 201 is a FRAM cell array, and storage unit 212 is a ferroelectric capacitor for storing binary information of the respective FRAM cell based on the switch between two polarization states of ferroelectric materials under an external electric field.

As shown in FIG. 2, memory cells 208 can be arranged in a two-dimensional (2D) array having rows and columns. Memory device 200 can include word lines 204 coupling peripheral circuits 202 and memory cell array 201 for controlling the switch of vertical transistors 210 in memory cells 208 located in a row, as well as bit lines 206 coupling peripheral circuits 202 and memory cell array 201 for sending data to and/or receiving data from memory cells 208 located in a column. That is, each word line 204 is coupled to a respective row of memory cells 208, and each bit line is coupled to a respective column of memory cells 208.

As shown in FIG. 2, in some implementations, vertical transistor 210 includes a semiconductor body 214 extending vertically (in the Z-direction) above the substrate (not shown). That is, semiconductor body 214 can extend above the top surface of the substrate to expose not only the top surface of semiconductor body 214, but also one or more side surfaces thereof. As shown in FIG. 2, for example, semiconductor body 214 can have a cuboid shape to expose four sides thereof. It is understood that semiconductor body 214 may have any suitable 3D shape, such as a polyhedron shape or a cylinder shape. That is, the cross-section of semiconductor body 214 in the plan view (e.g., in the X-Y plane) can have a square shape, a rectangular shape (or a trapezoidal shape), a circular (or an oval shape), or any other suitable shapes. Semiconductor body 214 can be formed from the substrate (e.g., by etching or epitaxy) and thus, has the same semiconductor material (e.g., silicon crystalline silicon) as the substrate (e.g., a silicon substrate).

As shown in FIG. 2, vertical transistor 210 can also include a gate structure 216 in contact with one or more sides of semiconductor body 214, i.e., in one or more planes of the side surface(s) of the active region. In other words, the active region of vertical transistor 210, i.e., semiconductor body 214, can be at least partially surrounded by gate structure 216. Gate structure 216 can include a gate dielectric 218 over one or more sides of semiconductor body 214, e.g., in contact with four side surfaces of semiconductor body 214 as shown in FIG. 2. Gate structure 216 can also include a gate electrode 220 over and in contact with gate dielectric 218. Gate dielectric 218 can include any suitable dielectric materials, such as silicon oxide, silicon nitride, silicon oxynitride, or high-k dielectrics. For example, gate dielectric 218 may include silicon oxide, i.e., gate oxide. Gate electrode 220 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 220 may include doped polysilicon, i.e., a gate poly. In some implementations, gate electrode 220 includes multiple conductive structures, such as a W layer over a TiN layer. It is understood that gate electrode 220 and word line 204 may be a continuous conductive structure in some examples. In other words, gate electrode 220 may be viewed as part of word line 204 that forms gate structure 216, or word line 204 may be viewed as the extension of gate electrode 220 to be coupled to peripheral circuits 202.

As shown in FIG. 2, vertical transistor 210 can further include a pair of a source and a drain (S/D, dope regions, a.k.a., source electrode and drain electrode) formed at the two ends of semiconductor body 214 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 216 in the vertical direction (the Z-direction). In other words, gate structure 216 is formed vertically between the source and drain. As a result, one or more channels (not shown) of vertical transistor 210 can be formed in semiconductor body 214 vertically between the source and drain when a gate voltage applied to gate electrode 220 of gate structure 216 is above the threshold voltage of vertical transistor 210. That is, each channel of vertical transistors 210 is also formed in the vertical direction along which semiconductor body 214 extends, according to some implementations.

In some implementations, as shown in FIG. 2, vertical transistor 210 is a multi-gate transistor. That is, gate structure 216 can be in contact with more than one side of semiconductor body 214 (e.g., four sides in FIG. 2) to form more than one gate, such that more than one channel can be formed between the source and drain in operation. The multi-gate vertical transistors can include double-gate vertical transistors (e.g., dual-side gate vertical transistors), tri-gate vertical transistors (e.g., tri-side gate vertical transistors), and gate-all-around (GAA) vertical transistors.

It is understood that although vertical transistor 210 is shown as a multi-gate transistor in FIG. 2, the vertical transistors disclosed herein may also include single-gate transistors. That is, gate structure 216 may be in contact with a single side of semiconductor body 214, for example, for the purpose of increasing the transistor and memory cell density. It is also understood that although gate dielectric 218 is shown as being separate (i.e., a separate structure) from other gate dielectrics of adjacent vertical transistors (not shown), gate dielectric 218 may be part of a continuous dielectric layer having multiple gate dielectrics of vertical transistors. It is further understood that in some examples, memory device 200 may include planar transistors, such as lateral multiple-gate transistors (e.g., FinFET), instead of vertical transistors 210.

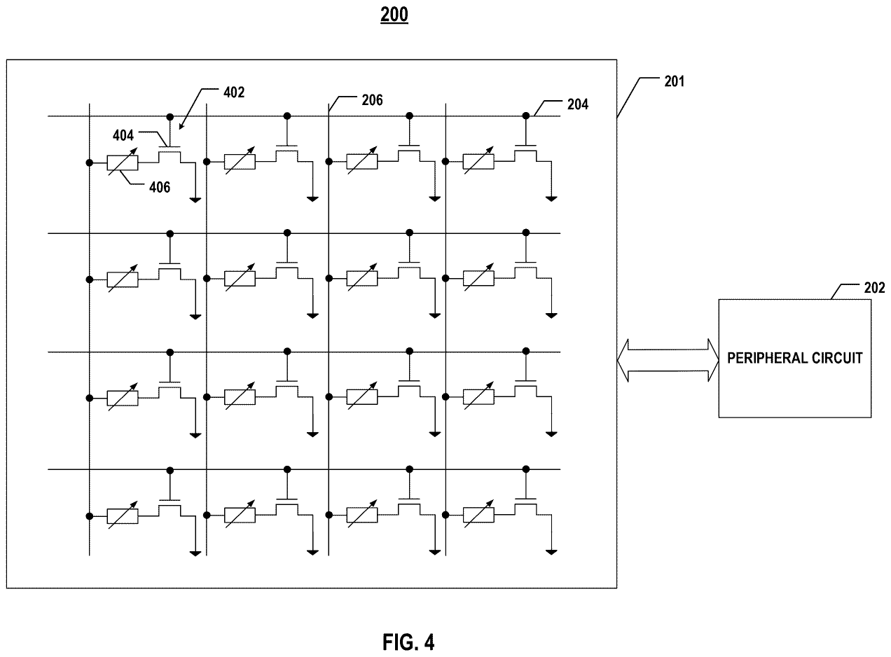

As shown in FIG. 2, storage unit 212 can be coupled to the source or the drain of vertical transistor 210. Storage unit 212 can include any devices that are capable of storing binary data (e.g., 0 and 1), including but not limited to, capacitors for DRAM cells and FRAM cells, and PCM elements for PCM cells. In some implementations, vertical transistor 210 controls the selection and/or the state switch of the respective storage unit 212 coupled to vertical transistor 210. In some implementations as shown in FIG. 3, each memory cell 208 is a DRAM cell 302 including a transistor 304 (e.g., vertical transistors 210 in FIG. 2 or planar transistors, such as FinFETs) and a capacitor 306 (e.g., an example of storage unit 212 in FIG. 2). The gate of transistor 304 (e.g., corresponding to gate electrode 220) may be coupled to word line 204, one of the source and the drain of transistor 304 may be coupled to bit line 206, the other one of the source and the drain of transistor 304 may be coupled to one electrode of capacitor 306, and the other electrode of capacitor 306 may be coupled to the ground. In some implementations as shown in FIG. 4, each memory cell 208 is a PCM cell 402 including a transistor 404 (e.g., vertical transistors 210 in FIG. 2 or planar transistors, such as FinFETs) and a PCM element 406 (e.g., an example of storage unit 212 in FIG. 2). The gate of transistor 404 (e.g., corresponding to gate electrode 220) may be coupled to word line 204, one of the source and the drain of transistor 404 may be coupled to the ground, the other one of the source and the drain of transistor 404 may be coupled to one electrode of PCM element 406, and the other electrode of PCM element 406 may be coupled to bit line 206.

Peripheral circuits 202 can be coupled to memory cell array 201 through bit lines 206, word lines 204, and any other suitable metal wirings. As described above, peripheral circuits 202 can include any suitable circuits for facilitating the operations of memory cell array 201 by applying and sensing voltage signals and/or current signals through word lines 204 and bit lines 206 to and from each memory cell 208. Peripheral circuits 202 can include various types of peripheral circuits formed using CMOS technologies.

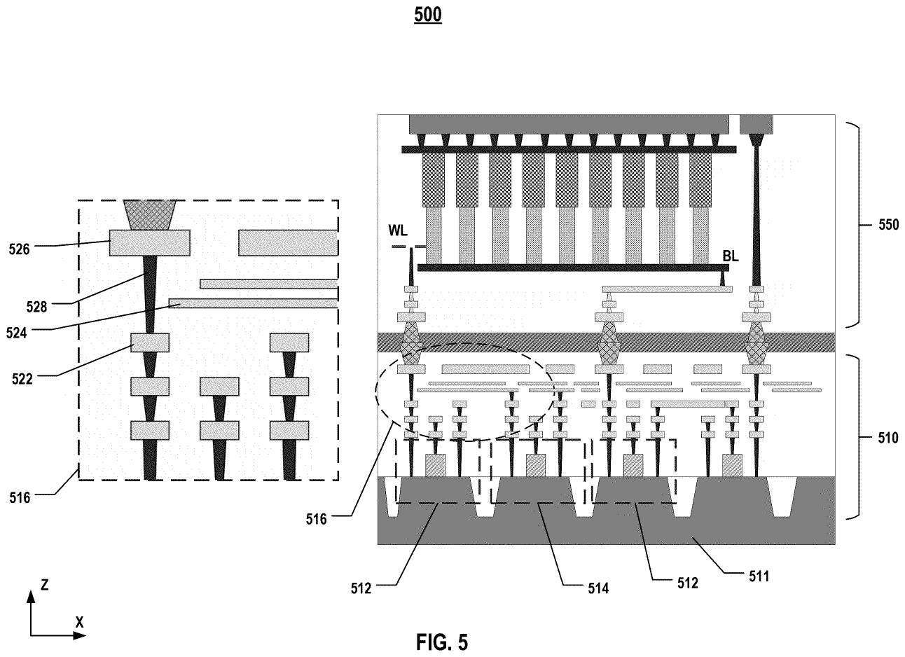

FIG. 5 illustrates a side view of a cross-section of a 3D memory device 500 including a peripheral circuit structure 510 and a memory array structure 550 stacked with the peripheral circuit structure 510. The peripheral circuit structure 510 is stacked with the memory array structure 550 along the Z-direction.

The peripheral circuit structure 510 includes a first periphery circuit 512 and a second periphery circuit 514 disposed on a substrate 511. In some implementations, the substrate 511 is a silicon substrate. In some implementations, the first periphery circuit 512 is a sense amplifier. In some implementations, the first periphery circuit 512 is a word line driver. In some implementations, the second periphery circuit 514 is a periphery circuit other than the sense amplifier and/or word line driver. In some implementations, the second periphery circuit 514 is a page buffer, a decoder (e.g., a row decoder and a column decoder), a precharge voltage driver, a discharge voltage driver, an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors).

The peripheral circuit structure 510 further includes an interconnection structure 516 disposed on the first periphery circuit 512 and the second periphery circuit 514. The interconnection structure 516 includes a first conductive structure 522, a second conductive structure 524, a third conductive structure 526, and a contact structure 528. As shown in FIG. 5, the first conductive structure 522, the second conductive structure 524, and the third conductive structure 526 extend in the X-direction and/or the Y-direction (the X-Y plane), and the contact structure 528 extends in the Z-direction perpendicular to the X-Y plane. In some implementations, the first conductive structure 522, the second conductive structure 524, and the third conductive structure 526 are in different layers stacked sequentially. In some implementations, the first conductive structure 522 is located in the metal 3 (M3) layer, the second conductive structure 524 is located in the metal 4 (M4) layer, and the third conductive structure 526 is located in the top metal (TM) layer. In some implementations, the second conductive structure 524 is located between the first conductive structure 522 and the third conductive structure 526 in the Z-direction.

It is understood that, in some implementations, the metal 3 (M3) layer, the metal 4 (M4) layer, and the top metal (TM) layer may be stacked sequentially, and each metal layer may include dielectric material and metal structures.

The contact structure 528 extends in the Z-direction and the contact structure 528 is connected between the first conductive structure 522 and the third conductive structure 526. In some implementations, the contact structure 528 is in direct contact with the first conductive structure 522 and the third conductive structure 526. In other words, the contact structure 528 is in direct contact with the first conductive structure 522 and the third conductive structure 526 without passing other routings or contacting other conductive structures or conductive layers. In some implementations, the contact structure 528 is insulated with the second conductive structure 524.

In some implementations, the first periphery circuit 512 is coupled to the third conductive structure 526 through the contact structure 528 and the first conductive structure 522. In some implementations, the first periphery circuit 512 is coupled to the third conductive structure 526 through the contact structure 528, the first conductive structure 522, and other conductive structures or routings without the second conductive structure 524. In some implementations, the second periphery circuit 514 is coupled to the second conductive structure 524. In some implementations, the second periphery circuit 514 is coupled to another third conductive structure 526 through another first conductive structure 522, the second conductive structure 524, and other conductive structures or routings.

In some implementations, the first periphery circuit 512 and the second periphery circuit 514 may be different types of periphery circuits. For example, the first periphery circuit 512 may be the sense amplifier and/or the word line driver and the second periphery circuit 514 may be periphery circuits other than the sense amplifier and the word line driver. For another example, the first periphery circuit 512 may be the sense amplifier and the second periphery circuit 514 may be the word line driver. In some implementations, the first periphery circuit 512 and the second periphery circuit 514 may be different parts of the same periphery circuit. For example, the first periphery circuit 512 and the second periphery circuit 514 may be different transistors of the same sense amplifier or the same word line driver. In some implementations, the first periphery circuit 512 and the second periphery circuit 514 may be the same type of periphery circuit. For example, the first periphery circuit 512 and the second periphery circuit 514 may be both the sense amplifier or may be both the word line driver.

In some implementations, as shown in FIG. 5, because of the manufacturing process discussed later, the contacting surface between the contact structure 528 and the third conductive structure 526 is greater than the contacting surface between the contact structure 528 and the first conductive structure 522. In other words, as shown in FIG. 5, the cross-sectional view of the contact structure 528 is a trapezoid.

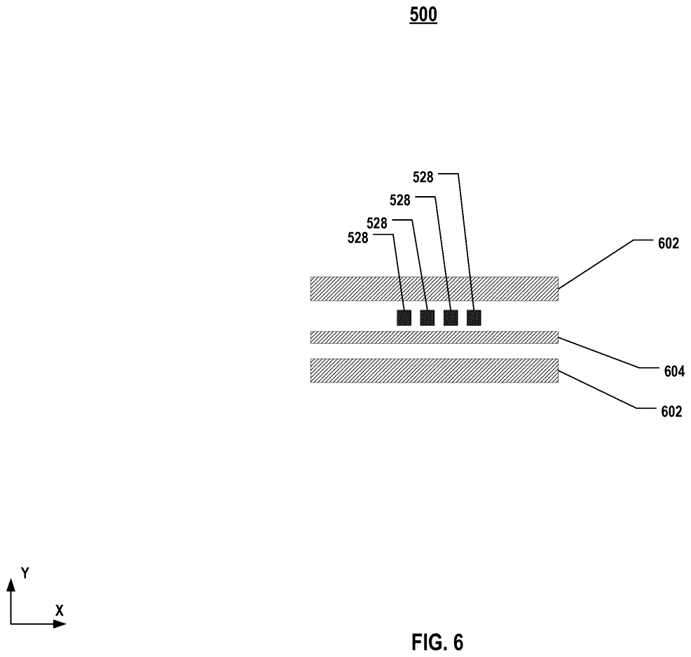

FIG. 6 illustrates a schematic plan view of the 3D memory device 500, according to some aspects of the present disclosure. In some implementations, FIG. 6 illustrates the plan view of the position of the second conductive structure 524. In some implementations, FIG. 6 illustrates the plan view of the position of the metal 4 (M4) layer. As shown in FIG. 6, the contact structure 528 passes through the X-Y plane of the metal 4 layer between two power lines 602. Because the area of the contact structure 528 on the X-Y plane is relatively smaller than the conductive structures, e.g., the second conductive structure 524, the saved area may be used for placing a connection line 604. In some implementations, the connection line 604 may be used for power lines between different second periphery circuits 514. In some implementations, the connection line 604 may be used for signal lines between different second periphery circuits 514. In some implementations, the connection line 604 may be used for power lines between the first periphery circuit 512 and the second periphery circuit 514. In some implementations, the connection line 604 may be used for signal lines between the first periphery circuit 512 and the second periphery circuit 514.

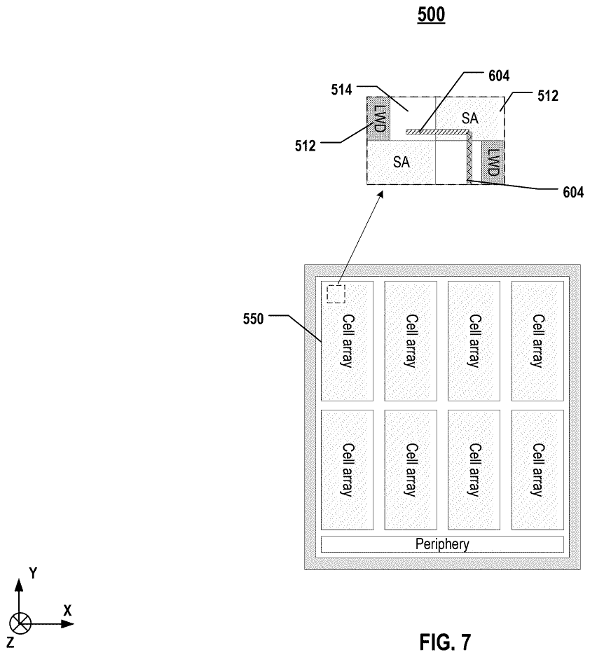

FIG. 7 illustrates a schematic plan view of the 3D memory device 500, according to some aspects of the present disclosure. As shown in FIG. 7, the peripheral circuit structure 510 overlaps the memory array structure 550 in the Z-direction. In some implementations, the projection of the peripheral circuit structure 510, including the first periphery circuit 512 and the second periphery circuit 514, along the Z-direction, is located in the area of the memory array structure 550.

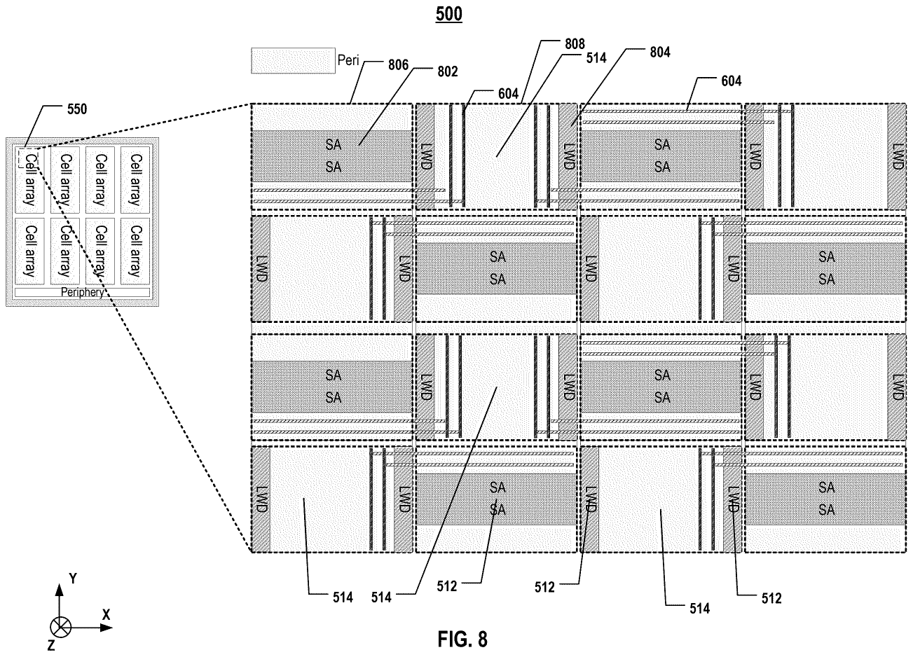

FIG. 8 illustrates a schematic plan view of the 3D memory device 500, according to some aspects of the present disclosure. As shown in FIG. 8, the projection of the peripheral circuit structure 510, including the first periphery circuit 512 and the second periphery circuit 514, along the Z-direction, is located in the area of the memory array structure 550. In some implementations, the second periphery circuit 514 is disposed between two adjacent first periphery circuits 512 on the substrate. In some implementations, the second periphery circuit 514 is disposed between two adjacent first periphery circuits 512 in the X-direction and/or in the Y-direction. For example, as shown in FIG. 8, the second periphery circuit 514 may be located between two word line drivers 804. For another example, as shown in FIG. 8, the second periphery circuit 514 may be located between two sense amplifiers 802. For a further example, as shown in FIG. 8, the second periphery circuit 514 may be surrounded by two word line drivers 804 and two sense amplifiers 802. In some implementations, as shown in FIG. 8, the second periphery circuit 514 may be located on two sides of the sense amplifier 802.

In some implementations, the projection of two sense amplifiers 802 can be located in the same memory block 806 of the memory array structure 550. In some implementations, the projection of two sense amplifiers 802 controlling adjacent memory blocks can be located in the same memory block 806 of the memory array structure 550. In some implementations, the projection of the sense amplifier 802 extends in the X-direction, as shown in FIG. 8. In some implementations, the projection of two word line drivers 804 can be located in the same memory block 808 of the memory array structure 550. In some implementations, the projection of two word line drivers 804 controlling adjacent memory blocks can be located in the same memory block 808 of the memory array structure 550. In some implementations, the projection of the word line driver 804 extends in the Y-direction, as shown in FIG. 8. In some implementations, the extension directions of the word line drivers 804 and/or the sense amplifiers 802 are not limited. In some implementations, the extension direction of the word line drivers 804 is perpendicular to the extension direction of the sense amplifiers 802. In some implementations, the second periphery circuit 514 is disposed between two word line drivers 804 in the same memory block. In some implementations, the second periphery circuit 514 is disposed on two sides of the sense amplifiers 802. It is understood that the arrangement of the first periphery circuit 512 and the second periphery circuit 514 in FIG. 8 is for illustration only, and other arrangement may be also suitable for application.

As discussed above, because the area of the contact structure 528 on the X-Y plane is relatively smaller than the conductive structures, e.g., the second conductive structure 524, the saved area may be used for placing the connection line 604. As shown in FIG. 8, in some implementations, the connection line 604 is used for connecting two second periphery circuits 514 located in two different memory blocks. In some implementations, the connection line 604 is used for connecting two second periphery circuits 514 located in adjacent bock areas. In some implementations, the connection line 604 may be used for power lines between different second periphery circuits 514. In some implementations, the connection line 604 may be used for signal lines between different second periphery circuits 514. It is understood that, in some implementations, the connection line 604 may be also used for connecting the first periphery circuit 512 and the second periphery circuit 514.

By using the structures described above, the contact structure 528 can extend from the lower metal layer, e.g., the first conductive structure 522, to the top metal layer, e.g., the third conductive structure 526, without going through the other middle metal layers, e.g., the second conductive structure 524. The contact structure 528 extends through multiple metal layers to replace the via-metal-via structure, the sense amplifiers and/or word line drivers can be directly connected to the top metal layer. As a result, the contact structure reduces routing path and space requirements, frees up additional space for other components, such as power lines, and reduces peripheral area. Additionally, the contact structure offers lower resistance than the via-metal-via structure, which can help minimize voltage drop loss in power lines.

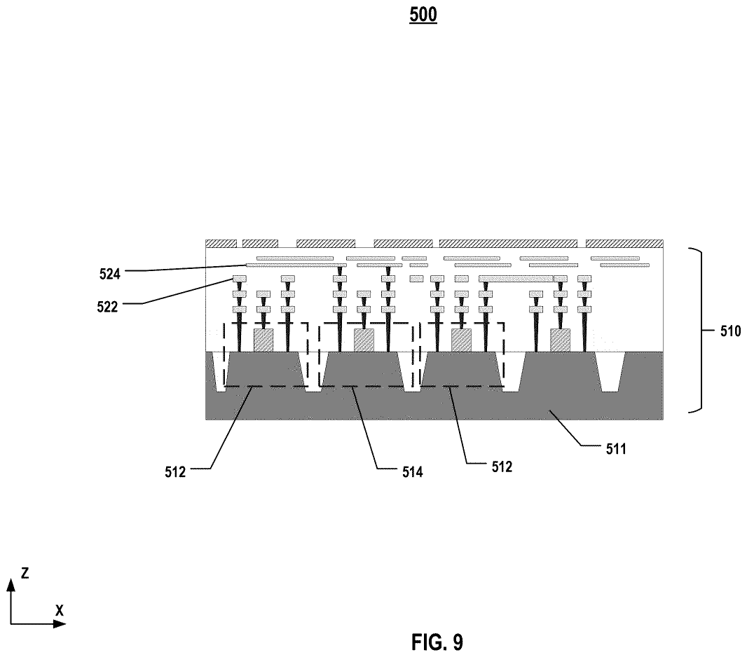

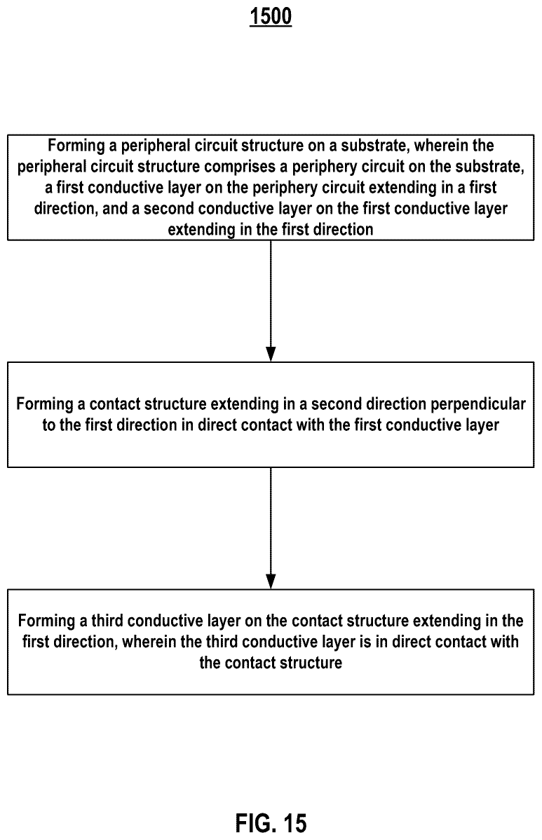

FIGS. 9-14 illustrate cross-sectional views of the 3D memory device 500 at various stages of a fabrication process, according to some implementations of the present disclosure. FIG. 15 illustrates a flowchart of method 1500 for forming the 3D memory device 500, according to some implementations of the present disclosure. For the purpose of better describing the present disclosure, the 3D memory device 500 in FIGS. 9-14 and method 1500 in FIG. 15 will be discussed together. It is understood that the operations shown in method 1500 are not exhaustive and that other operations may be performed as well before, after, or between any of the illustrated operations. Further, some of the operations may be performed simultaneously, or in a different order than shown in FIGS. 9-14 and FIG. 15.

As shown in FIG. 9 and operation 1502 of FIG. 15, a peripheral circuit structure 510 is formed on a substrate 511. The peripheral circuit structure includes a periphery circuit, including the first periphery circuit 512 and the second periphery circuit 514, on the substrate 511, a first conductive structure 522 on the periphery circuit extending in the X-direction and/or the Y-direction, and a second conductive structure 524 on the first conductive structure 522 extending in the X-direction and/or the Y-direction.

In some implementations, the substrate 511 is a silicon substrate. In some implementations. the first periphery circuit 512 is a sense amplifier. In some implementations, the first periphery circuit 512 is a word line driver. In some implementations, the second periphery circuit 514 is a periphery circuit other than the sense amplifier and/or word line driver. In some implementations, the second periphery circuit 514 is a page buffer, a decoder (e.g., a row decoder and a column decoder), a precharge voltage driver, a discharge voltage driver, an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors).

In some implementations, the first conductive structure 522 is formed on the first periphery circuit 512 and the second periphery circuit 514, and the first conductive structure is coupled to the first periphery circuit 512 and the second periphery circuit 514. In some implementations, the second conductive structure 524 is formed on the first conductive structure 522, and the second conductive structure 524 is coupled to the second periphery circuit 514. It is noted that, in some implementations, multiple first periphery circuits 512 may be formed on the substrate 511, and all first periphery circuits 512 are not connected to or not coupled to the second conductive structure 524. It is further noted that, in some implementations, multiple first periphery circuits 512 may be formed on the substrate 511, and some of the first periphery circuits 512 are not connected to or not coupled to the second conductive structure 524.

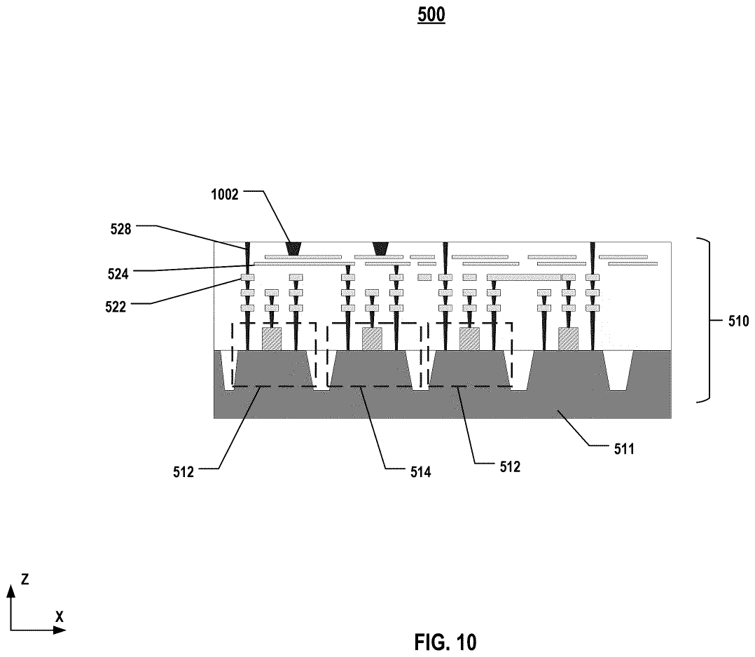

As shown in FIG. 10 and operation 1504 of FIG. 15, a contact structure 528 is formed extending in the Z-direction perpendicular to the X-direction and Y-direction in direct contact with the first conductive structure 522. In some implementations, an opening is formed extending in the Z-direction exposing the first conductive structure 522, and the contact structure 528 is then formed in the opening. In some implementations, the opening may be formed by dry etch, wet etch, or any suitable process. Because the opening is formed from the top of the peripheral circuit structure 510, the cross-sectional view of the contact structure 528 may be a trapezoid.

In some implementations, the contact structure 528 is formed on and in contact with only the first conductive structure 522, and the contact structure 528 is not in contact with the second conductive structure 524. In other words, the contact structure 528 is insulated with the second conductive structure 524.

In some implementations, a contact structure 1002 may be formed on the second conductive structure 524 as a top via, and the contact structure 1002 and the contact structure 528 may be formed by a same mask. In some implementations, the contact structure 1002 and the contact structure 528 may be formed by different masks.

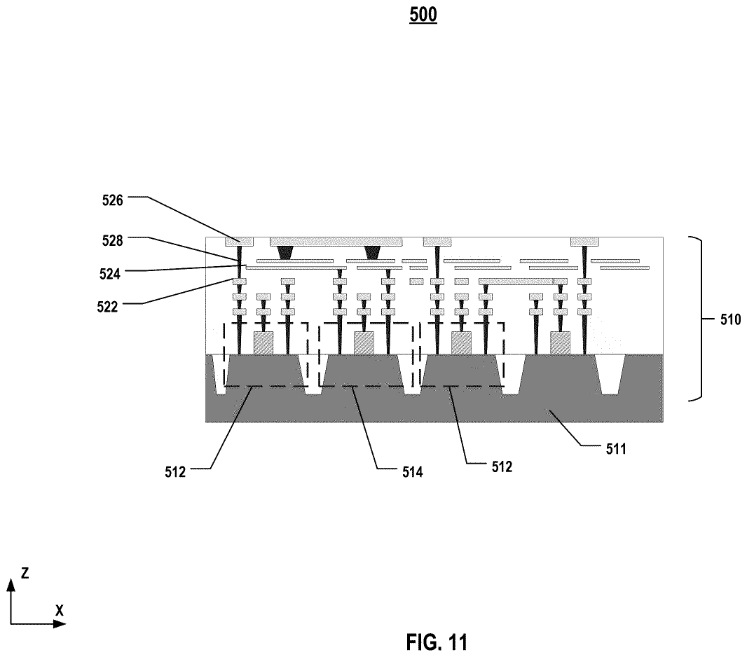

As shown in FIG. 11 and operation 1506 of FIG. 15, a third conductive structure 526 is formed on the contact structure 528 extending in the X-direction and/or the Y-direction. The third conductive structure 526 is in direct contact with the contact structure 528. In some implementations, another third conductive structure 526 is also formed on the second conductive structure 524 and in contact with the second conductive structure 524.

In some implementations, as shown in FIG. 11, the first periphery circuit 512 is coupled to the third conductive structure 526 through the contact structure 528 and the first conductive structure 522. In some implementations, the first periphery circuit 512 is coupled to the third conductive structure 526 through the contact structure 528, the first conductive structure 522, and other conductive structures or routings without the second conductive structure 524. In some implementations, the second periphery circuit 514 is coupled to the second conductive structure 524. In some implementations, the second periphery circuit 514 is coupled to another third conductive structure 526 through another first conductive structure 522, the second conductive structure 524, and other conductive structures or routings.

In some implementations, the first periphery circuit 512 and the second periphery circuit 514 may be different types of periphery circuits. For example, the first periphery circuit 512 may be the sense amplifier and/or the word line driver and the second periphery circuit 514 may be periphery circuits other than the sense amplifier and the word line driver. For another example, the first periphery circuit 512 may be the sense amplifier and the second periphery circuit 514 may be the word line driver. In some implementations, the first periphery circuit 512 and the second periphery circuit 514 may be different parts of the same periphery circuit. For example, the first periphery circuit 512 and the second periphery circuit 514 may be different transistors of the same sense amplifier or the same word line driver. In some implementations, the first periphery circuit 512 and the second periphery circuit 514 may be the same type of periphery circuit. For example, the first periphery circuit 512 and the second periphery circuit 514 may be both the sense amplifier or may be both the word line driver.

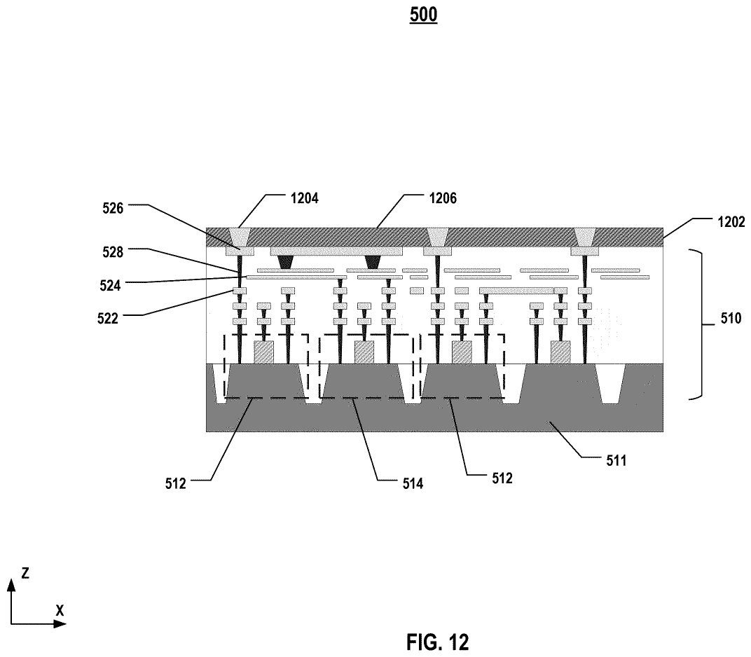

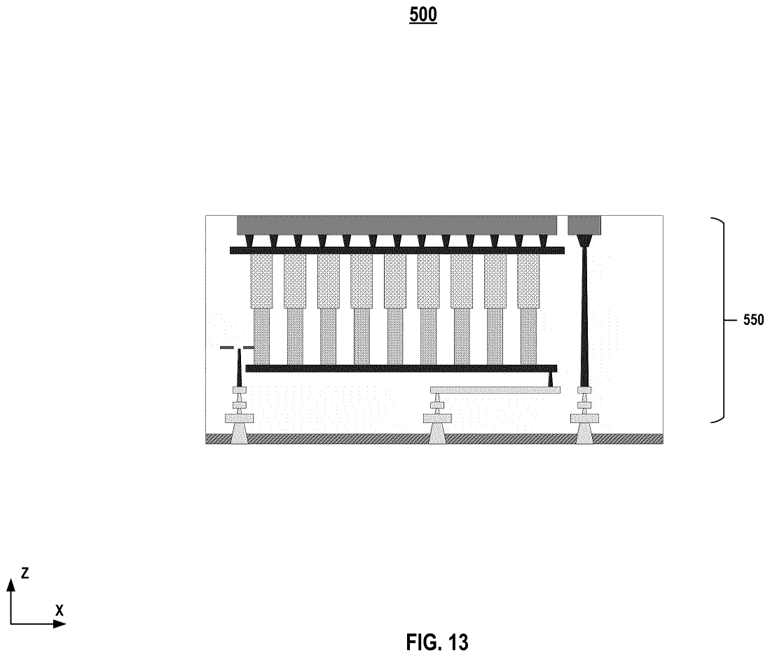

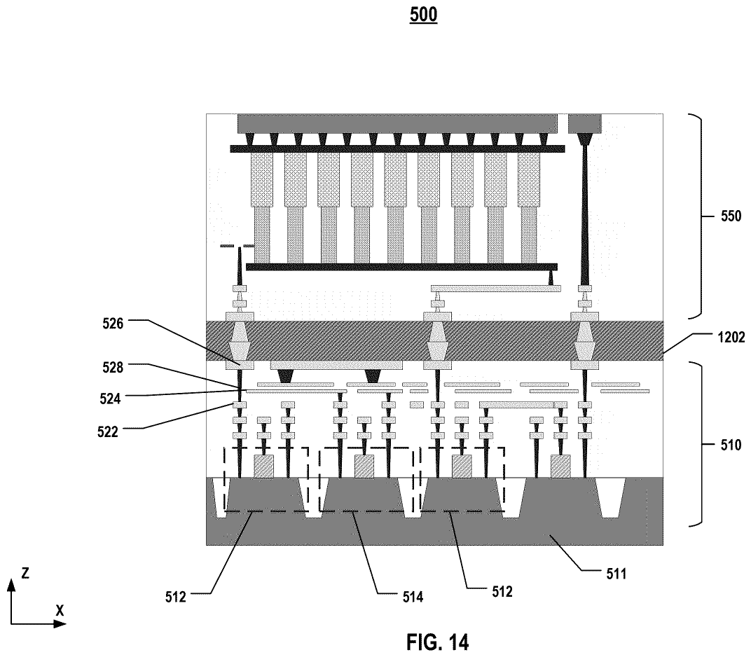

As shown in FIG. 12, a bonding layer 1202 may be formed on the peripheral circuit structure 510. In some implementations, the bonding layer 1202 may include a dielectric structure 1206 and a conductive bonding contact structure 1204. In some implementations, the third conductive structure 526 is in contact with the conductive bonding contact structure 1204. In some implementations, as shown in FIG. 13, a memory array structure 550 is formed. In some implementations, the memory array structure 550 is formed separately from the peripheral circuit structure 510. In some implementations, the memory array structure 550 and the peripheral circuit structure 510 may be formed on different substrates. Then, as shown in FIG. 14, the memory array structure 550 is bonded with the peripheral circuit structure 510 through the bonding layer 1202.

In some implementations, the peripheral circuit structure 510 may be formed on the substrate 511 first, and the memory array structure 550 is then formed on the peripheral circuit structure 510. In some implementations, the first periphery circuit 512 is coupled to a word line of the memory array structure 550. In some implementations, the first periphery circuit 512 is coupled to a bit line of the memory array structure 550.

By using the method 1500 described above, the contact structure 528 can extend from the lower metal layer, e.g., the first conductive structure 522, to the top metal layer, e.g., the third conductive structure 526, without going through the other middle metal layers, e.g., the second conductive structure 524. The contact structure 528 extends through multiple metal layers to replace the via-metal-via structure, the sense amplifiers and/or word line drivers can be directly connected to the top metal layer. As a result, the contact structure reduces routing path and space requirements, frees up additional space for other components, such as power lines, and reduces peripheral area. Additionally, the contact structure offers lower resistance than the via-metal-via structure, which can help minimize voltage drop loss in power lines.

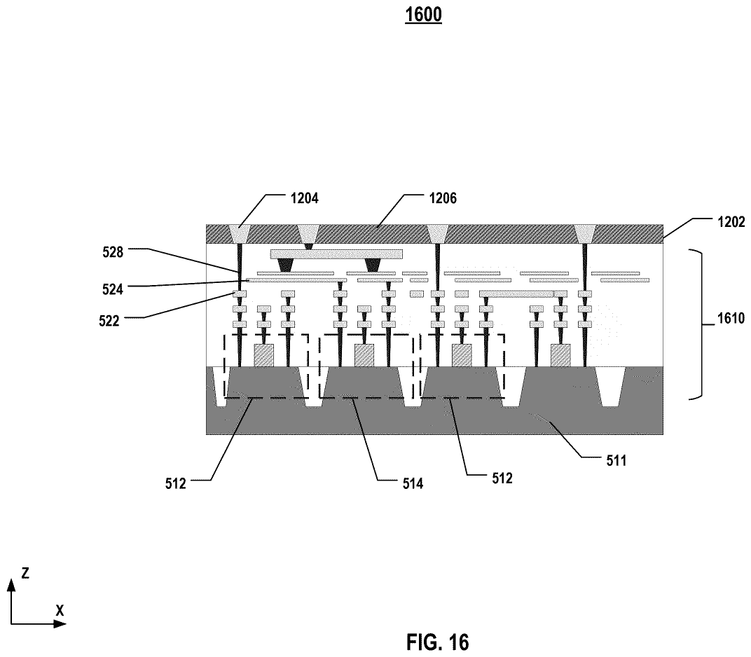

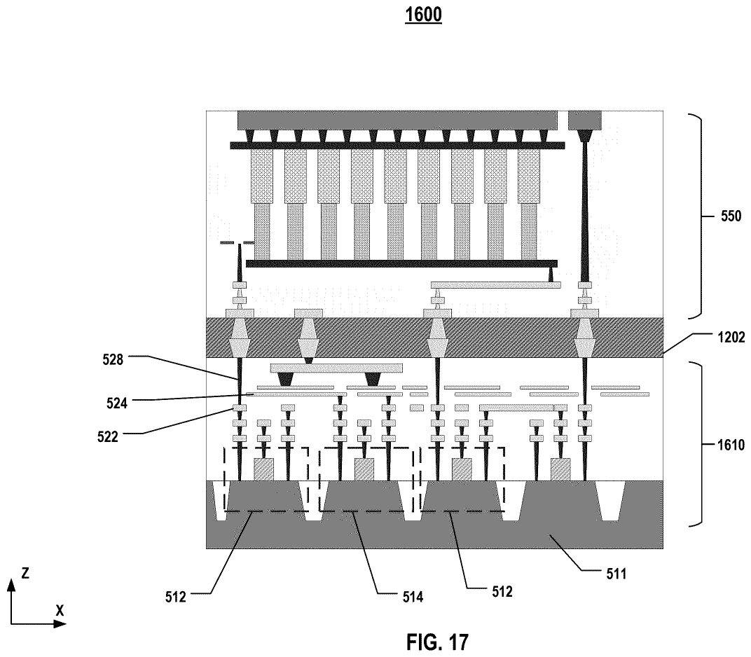

FIGS. 16-17 illustrate cross-sectional views of another exemplary 3D memory device 1600 at various stages of a fabrication process, according to some implementations of the present disclosure. As shown in FIG. 16, after operation 1504 of FIG. 15, the contact structure 528 is formed extending in the Z-direction perpendicular to the X-direction and Y-direction in direct contact with the first conductive structure 522. Then, the bonding layer 1202 is directly formed on the contact structure 528, and the conductive bonding contact structure 1204 is in direct contact with the contact structure 528. In other words, the third conductive structure 526 may be omitted or may be integrated with the conductive bonding contact structure 1204. In some implementations, the conductive bonding contact structure 1204 may be also connected to the second conductive structure 524 through other conductive structures or routings.

In some implementations, the contact structure 528 and the conductive bonding contact structure 1204 may be formed together by using the single-Damascene or dual-Damascene process. For example, after operation 1502 forming the first conductive structure 522 and the second conductive structure 524, the dielectric structure 1206 may be formed on the peripheral circuit structure 1610. The opening for the contact structure 528 and the trench for the conductive bonding contact structure 1204 may be formed in the peripheral circuit structure 1610 and in the dielectric structure 1206. Then a conductive material, e.g., Cu, may be formed in the opening and the trench to form the contact structure 528 and the conductive bonding contact structure 1204.

Then, as shown in FIG. 17, the memory array structure 550 is bonded with the peripheral circuit structure 1610 through the bonding layer 1202.

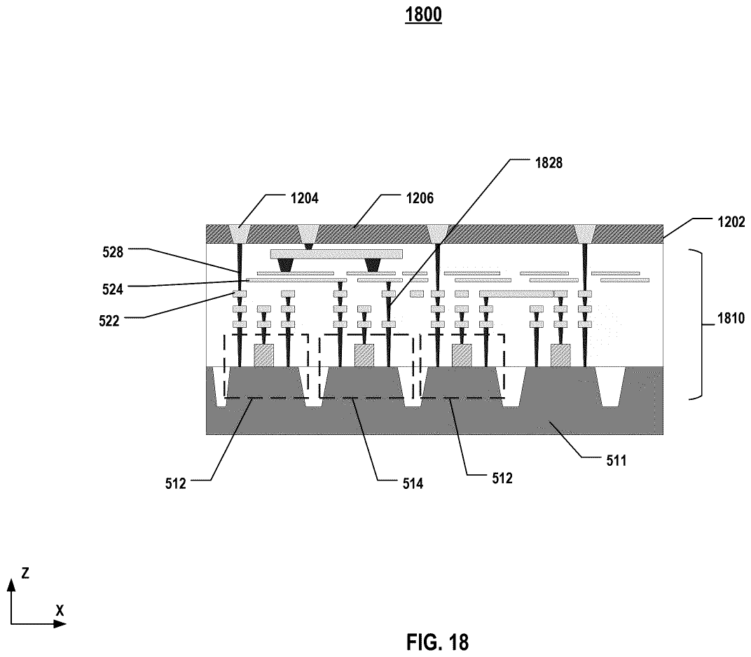

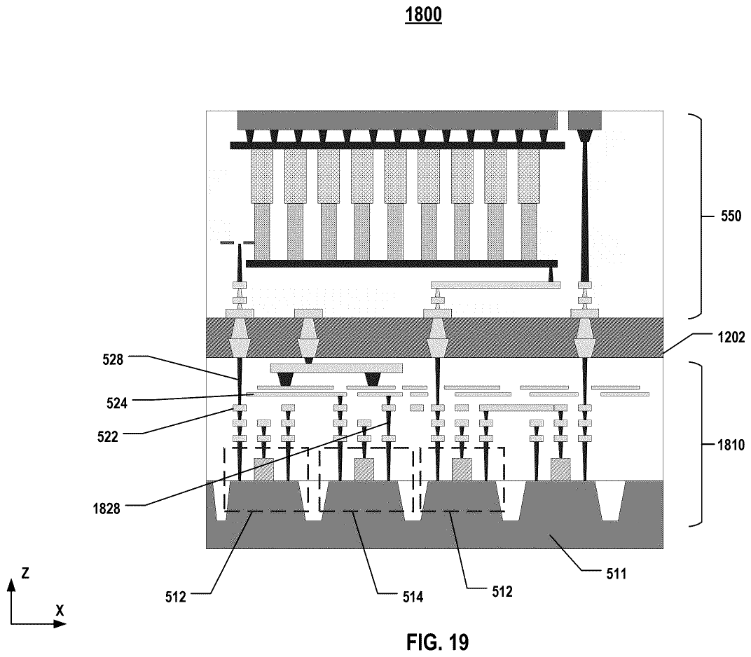

FIGS. 18-19 illustrate cross-sectional views of another exemplary 3D memory device 1800 at various stages of a fabrication process, according to some implementations of the present disclosure. As shown in FIG. 18, a second contact structure 1828 may be formed on the second periphery circuit 514. In some implementations, the second contact structure 1828 extends in the Z-direction connecting the second periphery circuit 514 to the first conductive structure 522 and the second conductive structure 524. In some implementations, the contact structure 528 and the second contact structure 1828 may be formed between different conductive structures. In some implementations, the contact structure 528 and the second contact structure 1828 may be formed in the same process. In some implementations, the contact structure 528 and the second contact structure 1828 may be formed sequentially.

Then, as shown in FIG. 19, the memory array structure 550 is bonded with the peripheral circuit structure 1810 through the bonding layer 1202.

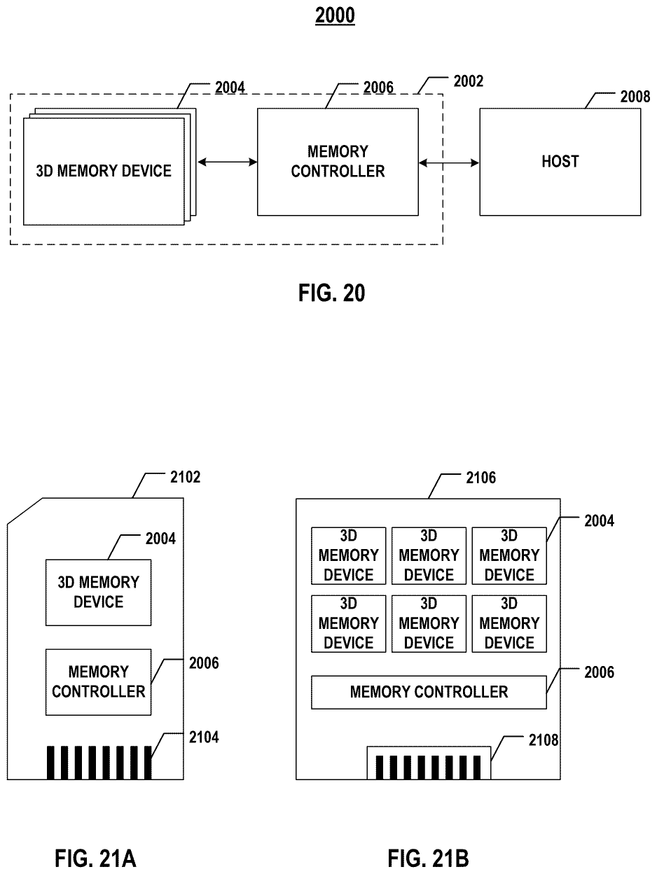

FIG. 20 illustrates a block diagram of a system 2000 having a memory device, according to some aspects of the present disclosure. System 2000 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 20, system 2000 can include a host 2008 and a memory system 2002 having one or more memory devices 2004 and a memory controller 2006. Host 2008 can be a processor of an electronic device, such as a central processing unit (CPU), or a system-on-chip (SoC), such as an application processor (AP). Host 2008 can be configured to send or receive the data to or from memory devices 2004.

Memory controller 2006 is coupled to memory device 2004 and host 2008 and is configured to control memory device 2004, according to some implementations. In some implementations, memory device 2004 can be the 3D memory device 500, 1600, or 1800 described above. Memory controller 2006 can manage the data stored in memory device 2004 and communicate with host 2008. In some implementations, memory controller 2006 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 2006 is designed for operating in a high duty-cycle environment SSDs or embedded multi-media-cards (eMMCs) used as data storage for mobile devices, such as smartphones, tablets, laptop computers, etc., and enterprise storage arrays. Memory controller 2006 can be configured to control operations of memory device 2004, such as read, erase, and program operations. In some implementations, memory controller 2006 is configured to control the array of memory cells through the first peripheral circuit 512 and the second periphery circuit 514. Memory controller 2006 can also be configured to manage various functions with respect to the data stored or to be stored in memory device 2004 including, but not limited to bad-block management, garbage collection, logical-to-physical address conversion, wear leveling, etc. In some implementations, memory controller 2006 is further configured to process error correction codes (ECCs) with respect to the data read from or written to memory device 2004. Any other suitable functions may be performed by memory controller 2006 as well, for example, formatting memory device 2004. Memory controller 2006 can communicate with an external device (e.g., host 2008) according to a particular communication protocol. For example, memory controller 2006 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 2006 and one or more memory devices 2004 can be integrated into various types of storage devices, for example, be included in the same package, such as a universal Flash storage (UFS) package or an eMMC package. That is, memory system 2002 can be implemented and packaged into different types of end electronic products. In one example as shown in FIG. 21A, memory controller 2006 and a single memory device 2004 may be integrated into a memory card 2102. Memory card 2102 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 2102 can further include a memory card connector 2104 coupling memory card 2102 with a host (e.g., host 2008 in FIG. 20). In another example as shown in FIG. 21B, memory controller 2006 and multiple memory devices 2004 may be integrated into an SSD 2106. SSD 2106 can further include an SSD connector 2108 coupling SSD 2106 with a host (e.g., host 2008 in FIG. 20). In some implementations, the storage capacity and/or the operation speed of SSD 2106 is greater than those of memory card 2102.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A semiconductor device, comprising:
a peripheral circuit structure comprising:
a periphery circuit disposed on a substrate; and
a first interconnection structure disposed on the periphery circuit, the first interconnection structure comprising:
a first conductive structure extending in a first direction;
a second conductive structure extending in the first direction;
a third conductive structure extending in the first direction, wherein the second conductive structure is disposed between the first conductive structure and the third conductive structure in a second direction perpendicular to the first direction; and
a contact structure extending in the second direction in direct contact with the first conductive structure and the third conductive structure.

2. The semiconductor device of claim 1, further comprising:
a memory array structure stacked with the peripheral circuit structure along the second direction.

3. The semiconductor device of claim 2, wherein the periphery circuit comprises a first periphery circuit and a second periphery circuit, and the first periphery circuit is connected to the third conductive structure through the contact structure and the first conductive structure.

4. The semiconductor device of claim 3, wherein the second periphery circuit is connected to the second conductive structure.

5. The semiconductor device of claim 3, wherein the first periphery circuit comprises a sense amplifier or a word line driver.

6. The semiconductor device of claim 1, wherein a first contacting surface between the contact structure and the third conductive structure is greater than a second contacting surface between the contact structure and the first conductive structure.

7. The semiconductor device of claim 2, wherein the periphery circuit overlaps the memory array structure in the second direction.

8. The semiconductor device of claim 3, wherein projections of two first periphery circuits controlling two adjacent memory blocks are in a same memory block of the memory array structure in the second direction.

9. The semiconductor device of claim 8, wherein the third conductive structure is in direct contact with the conductive bonding contact structure.

10. The semiconductor device of claim 8, wherein the third conductive structure is in contact with the conductive bonding contact structure.

11. The semiconductor device of claim 8, wherein the third conductive structure comprises the conductive bonding contact structure.

12. The semiconductor device of claim 8, wherein the first periphery circuit is coupled to a word line of the memory array structure or a bit line of the memory array structure.

13. A system, comprising:
a semiconductor device, comprising:
a peripheral circuit structure comprising:
a periphery circuit disposed on a substrate; and
a first interconnection structure disposed on the periphery circuit, the first interconnection structure comprising:
a first conductive structure extending in a first direction;
a second conductive structure extending in the first direction;
a third conductive structure extending in the first direction, wherein the second conductive structure is disposed between the first conductive structure and the third conductive structure in a second direction perpendicular to the first direction; and
a contact structure extending in the second direction in direct contact with the first conductive structure and the third conductive structure; and
a memory controller coupled to the semiconductor device and configured to control the semiconductor device.

14. A method for forming a semiconductor device, comprising:
forming a peripheral circuit structure on a substrate, wherein the peripheral circuit structure comprises a periphery circuit on the substrate, a first conductive structure on the periphery circuit extending in a first direction, and a second conductive structure on the first conductive structure extending in the first direction;
forming a contact structure extending in a second direction perpendicular to the first direction in direct contact with the first conductive structure; and
forming a third conductive structure on the contact structure extending in the first direction, wherein the third conductive structure is in direct contact with the contact structure.

15. The method of claim 14, wherein the periphery circuit comprises a first periphery circuit and a second periphery circuit, and the first periphery circuit is connected to the third conductive structure through the contact structure and the first conductive structure.

16. The method of claim 15, wherein forming the peripheral circuit structure on the
substrate, comprises:
forming the first conductive structure on the first periphery circuit and the second periphery circuit, wherein the first conductive structure is coupled to the first periphery circuit; and
forming the second conductive structure on the first conductive structure, wherein the second conductive structure is coupled to the second periphery circuit.

17. The method of claim 15, wherein the first periphery circuit comprises a sense amplifier or a word line driver.

18. The method of claim 15, wherein forming the contact structure extending in the
second direction in direct contact with the first conductive structure, comprises:
forming an opening extending in the second direction exposing the first conductive structure; and
forming the contact structure in the opening.

19. The method of claim 18, wherein forming the contact structure in the opening, comprises:
forming the contact structure in the opening without contacting the second conductive structure.

20. The method of claim 14, further comprising:
forming a memory array structure; and
bonding the memory array structure with the peripheral circuit structure.
